(19) United States
(12) Patent Application Publication
(10) Pub. No.: US 2017/0148495 A1
(43) Pub. Date: May 25, 2017

(54) INPUT RECEIVER CIRCUIT

(71) Applicant: Micron Technology, Inc., Boise, ID (US)

(72) Inventor: Yasuhiro Takai, Sagamihara (JP)

(21) Appl. No.: 14/947,122

(22) Filed: Nov. 20, 2015

(51) Int. Cl. G11C 7/10

(52) U.S. Cl. CPC G11C 7/1078

(57) ABSTRACT

Apparatuses for receiving an input signal in a semiconductor device are described. An example apparatus includes an input node; a reference node supplied with a reference voltage; first, second, third and fourth nodes; a first transistor coupled between the first node and the second node, the first transistor having a gate coupled to the input node; a second transistor coupled between the first node and the third node, the second transistor having a gate coupled to the reference node; a third transistor coupled between the second node and the fourth node, the third transistor having a gate coupled to the third node; a fourth transistor coupled between the third node and the fourth node, the fourth transistor having a gate coupled to the third node; and a capacitor coupled between the input node and the third node.

### BACKGROUND

High data reliability, high speed of memory access, and reduced chip size are features that are demanded from semiconductor memory.

In recent years, there has been an effort to increase access speed while reducing power consumption for semiconductor devices. As part of that effort to increase access speed, it may be desirable to include input receiver circuits having faster operation in input buffers for receiving address signals, command signals and clock signals. However, a large propagation time difference between a signal rise time and a signal fall time of an input signal may cause memory devices to not meet timing specifications. Input buffers with fast input operation and a direct current (DC) reduction may be effective approach to low power consumption and high-speed access.

Along these lines, an input buffer including a combination of P/N differential amplifiers has been proposed. One approach for faster access speed at the input receiver circuits is to keep a margin for a window time. U.S. Pat. No. 6,137,320 describes a de-emphasis quad-coupled receiver (QCR) as the input receiver circuit. FIG. 1 is a circuit diagram of an example of the QCR type input receiver circuit. For example, a ground voltage VSS and a positive voltage VDD are supplied to gates of a PMOS transistor connected to a VDD voltage terminal and an NMOS transistor connected to a VSS voltage terminal in the QCR of FIG. 1, respectively, when the QCR is activated. A tail PMOS transistor and a tail NMOS transistor in the QCR receive the voltages VSS and VDD at their gates, respectively. Thus, the tail PMOS transistor and the tail NMOS transistor are activated to increase current driving capability with a substantially small transistor size while omitting a bias circuit that consumes power in a stand-by state. In this circuit, when an input signal rises, an NMOS transistor receiving the input signal becomes greater in current driving capability and a PMOS transistor receiving the input signal becomes weaker in current driving capability. As a result, PIN2B falls, which causes an output node to rise.

### SUMMARY

According to a first aspect of the present disclosure, there is provided an apparatus including an input node; a reference node supplied with a reference voltage; first, second, third and fourth nodes; a first transistor coupled between the first node and the second node, the first transistor having a gate coupled to the input node; a second transistor coupled between the first node and the third node, the second transistor having a gate coupled to the reference node; a third transistor coupled between the second node and the fourth node, the third transistor having a gate coupled to the third node; a fourth transistor coupled between the third node and the fourth node, the fourth transistor having a gate coupled to the third node; and a capacitor coupled between the input node and the third node. In one embodiment, the apparatus may further include fifth, sixth and seventh nodes; a fifth transistor coupled between the fifth node and the sixth node; a sixth transistor coupled between the fifth node and the third node; a seventh transistor coupled between the sixth node and the seventh node; and an eighth transistor coupled between the third node and the seventh node. The fifth transistor may have a gate coupled to the input node. The sixth transistor may have a gate coupled to the reference node.

In one embodiment, a gate of the seventh transistor and a gate of the eighth transistor may be coupled to the third node. In another embodiment, the apparatus may further include an additional capacitor coupled between the input node and the eighth node, and the gate of the seventh transistor and the gate of the eighth transistor may be coupled to the eighth node.

According to another aspect of the present disclosure, there is provided an input receiver circuit including an input node supplied with an input signal; a reference node supplied with a reference voltage; a first amplifier; a second amplifier; an output node; an inverter; a feedback resistor; and a first capacitor. The first amplifier includes first, second, third and fourth nodes; a first transistor coupled between the first node and the second node, the first transistor having a gate coupled to the input node; a second transistor coupled between the first node and the third node, the second transistor having a gate coupled to the reference node; a third transistor coupled between the second node and the fourth node, the third transistor having a gate coupled to the third node; and a fourth transistor coupled between the third node and the fourth node, the fourth transistor having a gate coupled to the third node. The second amplifier includes: fifth, sixth and seventh nodes; a fifth transistor coupled between the fifth node and the sixth node, the fifth transistor having a gate coupled to the input node; a sixth transistor coupled between the fifth node and the third node, the sixth transistor having a gate coupled to the reference node; a seventh transistor coupled between the sixth node and the seventh node, the seventh transistor; and an eighth transistor coupled between the third node and the seventh node, the eighth transistor. The inverter receives a signal from the sixth node and further inverts the signal to an output signal supplied to the output node. The feedback resistor is coupled between the sixth node and the output node. The first capacitor is coupled between the input node and the third node.

The input receiver circuit may further include a ninth transistor coupled between the first node and the seventh node and a tenth transistor coupled between the fourth node and the fifth node. In one embodiment, a gate of the ninth transistor receives a first activation signal and a gate of the tenth transistor receives a second activation signal which is a complementary signal of the first activation signal. In another embodiment, the gate of the ninth transistor receives a first bias signal and the gate of the tenth transistor receives a second bias signal, wherein the first bias signal and the second bias signal are generated externally. In another embodiment, the gate of the ninth transistor is coupled to the third node and the gate of the tenth transistor is coupled to the eighth node.

### BRIEF DESCRIPTION OF THE DRAWINGS

FIG. 1 is a circuit diagram of an example of a quad-coupled receiver (QCR) type input receiver circuit.

FIG. 2 is a block diagram of a semiconductor device in accordance with the present disclosure.

FIG. 3 is a circuit diagram of an example of an input receiver circuit according to an embodiment of the present disclosure.

FIG. 4A is a timing diagram of internal signals of the input receiver circuit of FIG. 1.

FIG. 4B is a timing diagram of internal signals of the input receiver circuit according to an embodiment of the present disclosure.

FIG. 5 is a circuit diagram of an example of an input receiver circuit according to an embodiment of the present disclosure.

FIG. 6 is a circuit diagram of an example of an input receiver circuit according to an embodiment of the present disclosure.

FIG. 7 is a circuit diagram of an example of an input receiver circuit according to an embodiment of the present disclosure.

### DETAILED DESCRIPTION OF PREFERRED EMBODIMENTS

Various embodiments of the present disclosure will be explained below in detail with reference to the accompanying drawings. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessary mutually exclusive, as some disclosed embodiments can be combined with one or more other disclosed embodiments to form new embodiments.

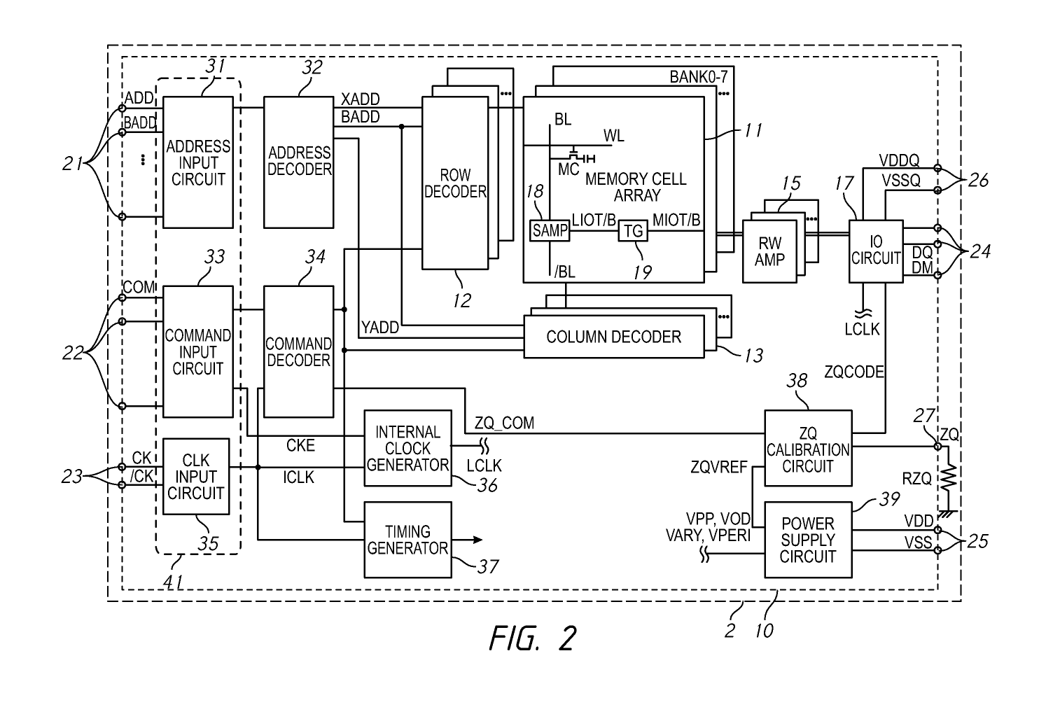

FIG. 2 is a block diagram of a semiconductor device in accordance with the present disclosure. The semiconductor device 10 may be a DDR4 SDRAM integrated into a single semiconductor chip, for example. The semiconductor device 10 may be mounted on an external substrate 2 that is a memory module substrate, a mother board or the like. The external substrate 2 employs an external resistor R_{ZQ} that is connected to a calibration terminal ZQ 27 of the semiconductor device 10. The external resistor R_{ZQ} is a reference impedance of a ZQ calibration circuit 38. In the present embodiment, the external resistor R_{ZQ} is coupled to a ground potential.

As shown in FIG. 2, the semiconductor device 10 includes a memory cell array 11.

The memory cell array 11 includes a plurality of banks, each bank including a plurality of word lines WL, a plurality of bit lines BL, and a plurality of memory cells MC arranged at intersections of the plurality of word lines WL and the plurality of bit lines BL. The selection of the word line WL is performed by a row decoder 12 and the selection of the bit line BL is performed by a column decoder 13. Sense amplifiers 18 are coupled to corresponding bit lines BL and connected to local I/O line pairs LIOT/B. Local IO line pairs LIOT/B are connected to main IO line pairs MIOT/B via transfer gates TG 19 which function as switches.

Turning to the explanation of a plurality of external terminals included in the semiconductor device 10, the plurality of external terminals includes address terminals 21, command terminals 22, clock terminals 23, data terminals 24, power supply terminals 25 and 26, and the calibration terminal ZQ 27. An input signal block 41 may include the address terminals 21, the command terminals 22 and the clock terminals 23 may include input buffers that will be later described in detail, according to one embodiment. The data terminals 24 may be coupled to output buffers for read operations of memories. Alternatively, the data terminals 24 may be coupled to input buffers for read/write access of the memories. FIG. 2 shows an example of dynamic random access memory (DRAM), however, any device having external terminals for signal input/output may be included as the external terminals of embodiments of the present disclosure.

The address terminals 21 are supplied with an address signal ADD and a bank address signal BADD. The address signal ADD and the bank address signal BADD supplied to the address terminals 21 are transferred via an address input circuit 31 to an address decoder 32. The address decoder 32 receives the address signal ADD and supplies a decoded row address signal XADD to the row decoder 12, and a decoded column address signal YADD to the column decoder 13. The address decoder 32 also receives the bank address signal BADD and supplies the bank address signal BADD to the row decoder 12, and the column decoder 13.

The command terminals 22 are supplied with a command signal COM. The command signal COM may include one or more separate signals. The command signal COM input to the command terminals 21 is input to a command decoder 34 via the command input circuit 33. The command decoder 34 decodes the command signal COM to generate various internal command signals. For example, the internal commands may include a row command signal to select a word line and a column command signal, such as a read command or a write command, to select a bit line, and a calibration signal ZQC provided to the ZQ calibration circuit 38.

Accordingly, when a read command is issued and a row address and a column address are timely supplied with the read command, read data is read from a memory cell MC in the memory cell array 11 designated by these row address and column address. The read data DQ is output externally from the data terminals 24 via a read/write amplifier 15 and an input/output circuit 17. Similarly, when the write command is issued and a row address and a column address are timely supplied with this command, and then write data DQ is supplied to the data terminals 24, the write data DQ is supplied via the input/output circuit 17 and the read/write amplifier 15 to the memory cell array 11 and written in the memory cell MC designated by the row address and the column address.

The clock terminals 23 are supplied with external clock signals CK and /CK, respectively. These external clock signals CK and /CK are complementary to each other and are supplied to a clock input circuit 35. The clock input circuit 35 receives the external clock signals CK and /CK and generates an internal clock signal ICLK. The internal clock signal ICLK is supplied to an internal clock generator 36 and thus a phase controlled internal clock signal LCLK is generated based on the received internal clock signal ICLK and a clock enable signal CKE from the command input circuit 33. Although not limited thereto, a DLL circuit can be used as the internal clock generator 36. The phase controlled internal clock signal LCLK is supplied to the input/output circuit 17 and is used as a timing signal for determining an output timing of the read data DQ. The internal clock signal ICLK is also supplied to a timing generator 37 and thus various internal clock signals can be generated.

The power supply terminals 25 are supplied with power supply potentials VDD and VSS. These power supply potentials VDD and VSS are supplied to an internal power supply circuit 39. The internal power supply circuit 39 generates various internal potentials VPP, VOD, VARY, VPERI, and the like and a reference potential ZQVREF based on the power supply potentials VDD and VSS. The internal potential VPP is mainly used in the row decoder 12, the internal potentials VOD and VARY are mainly used in the sense amplifiers 18 included in the memory cell array 11, and the internal potential VPERI is used in many other circuit blocks. The reference potential ZQVREF is used in the ZQ calibration circuit 38.

The power supply terminals 26 are supplied with power supply potentials VDDQ and VSSQ. These power supply potentials VDDQ and VSSQ are supplied to an output buffer (not shown) included in the input/output circuit 17. The power supply potentials VDDQ and VSSQ may be the same potentials as the power supply potentials VDD and VSS that are supplied to the power supply terminals 25, respectively. However, the dedicated power supply potentials VDDQ and VSSQ may be used for the output buffer in the input/output circuit 17 so that power supply noise generated by the input/output circuit 17 does not propagate to the other circuit blocks.

The calibration terminal ZQ is connected to the calibration circuit 38. The calibration circuit 38 performs a calibration operation with reference to an impedance of an external resistance Re and the reference potential ZQVREF, when activated by the calibration signal ZQ_COM. An impedance code ZQCODE obtained by the calibration operation is supplied to the input/output circuit 17, and thus an impedance of an output buffer (not shown) included in the input/output circuit 17 is specified.

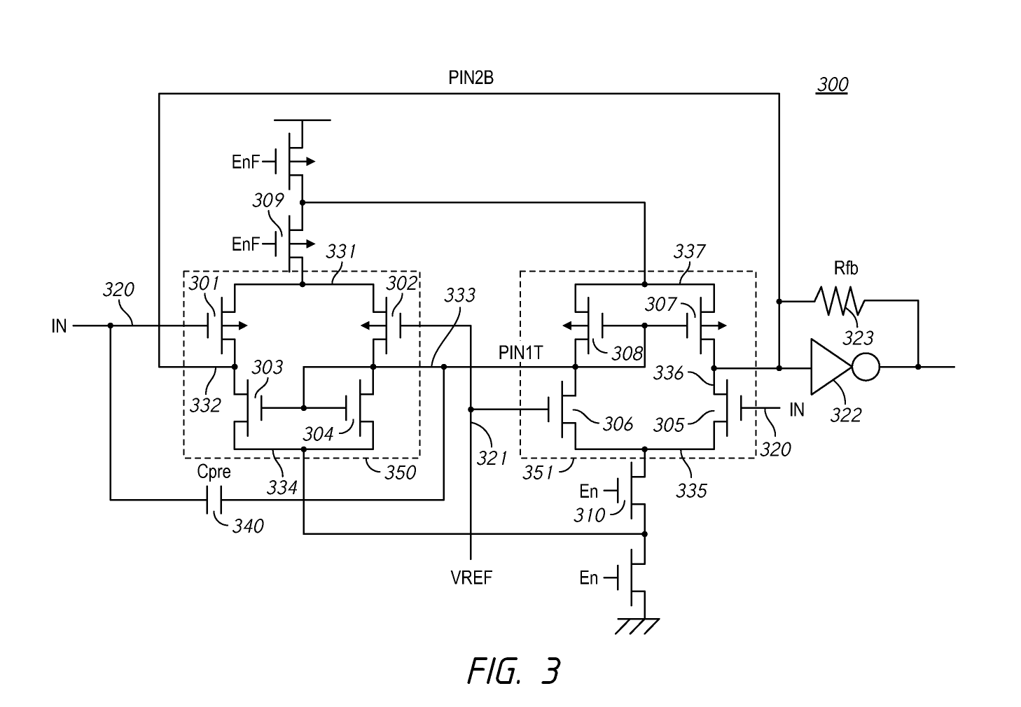

FIG. 3 is a circuit diagram of an example of an input receiver circuit according to an embodiment of the present disclosure. A quad-coupled receiver (QCR) type input receiver circuit 300 of FIG. 3 may be used for an input buffer of any of the address input circuit 31, the command input circuit 33, or the clock input circuit 35 in FIG. 2. The input receiver circuit 300 includes an input node 320 that is supplied with an input signal and a reference node 321 that is supplied with a reference voltage VREF. The input receiver circuit 300 also includes a first amplifier circuit 350 including a plurality of transistors. For example, a first transistor 301, which is coupled between a first node 331 and a second node 332, has a gate coupled to the input node 320. A second transistor 302, which is coupled between the first node 331 and a third node 333, has a gate coupled to the reference node 321. A third transistor 303, which is coupled between the second node 332 and a fourth node 334, has a gate coupled to the third node 333. A fourth transistor 304, which is coupled between the third node 333 and the fourth node 334, has a gate coupled to the third node 333.

The input receiver circuit 300 may also include a second amplifier circuit 351 including a plurality of transistors. For example, a fifth transistor 305, which is coupled between a fifth node 335 and a sixth node 336, has a gate coupled to the input node 320. A sixth transistor 306, which is coupled between the fifth node 335 and the third node 333, has a gate coupled to the reference node 321. A seventh transistor 307, which is coupled between the sixth node 336 and a seventh node 337, has a gate coupled to the third node. An eighth transistor 308, which is coupled between the third node 333 and the seventh node 337, has a gate coupled to the third node 333.

The input receiver circuit 300 may also include transistors to which a ground voltage VSS and a positive voltage VDD are supplied. A ninth transistor 309 that may be coupled between the first node and the seventh node that has a gate coupled to a complementary signal of an activation signal. A tenth transistor 310 may be coupled between the fourth node and the fifth node that has a gate coupled to the activation signal. The activation signal may be provided to enable or disable the input receiver circuit 300. In the embodiment of FIG. 3, the first, second, seventh, eighth, and ninth transistors 301, 302, 307, 308, and 309 may be P channel field effect transistors, and the third, fourth, fifth, sixth, and tenth transistors 303, 304, 305, 306, and 310 may be N channel field effect transistors. In other embodiments, however, the first through eighth transistors may be different types of transistors, and/or transistors with different conductivity types to that described with reference to the embodiment of FIG. 3. The input receiver circuit 300 may also include an inverter 322 and a feedback resistor 323. The inverter 322 receives a signal from the sixth node and in response, provides an output signal to the output node. The feedback resistor 323 coupled between the sixth node and the output node for suppressing amplitude of a signal at the second node (PIN2B) that helps the circuit to transmit the output signal with very high speed.

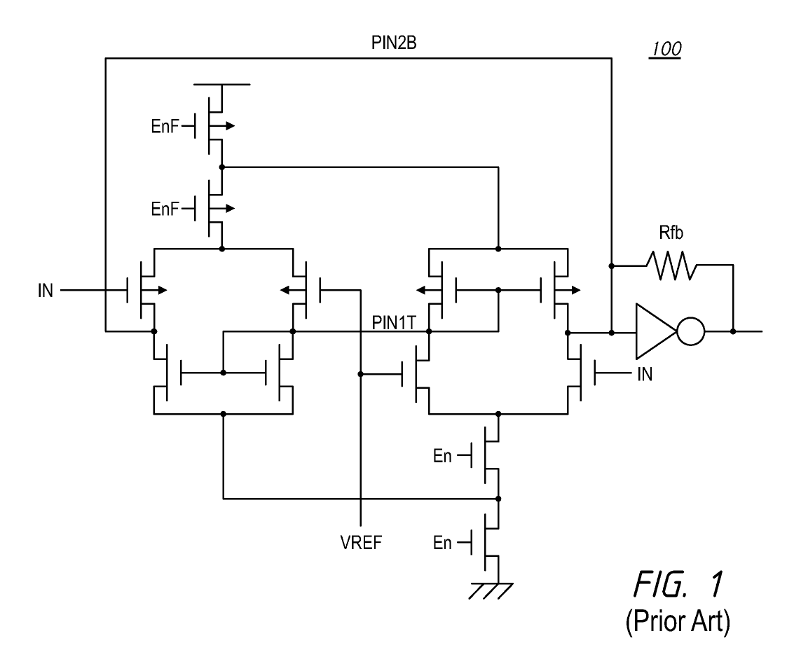

The input receiver circuit 300 of this embodiment in FIG. 3 differs from the QCR type input receiver circuit in FIG. 1 in that the input receiver circuit 300 also includes a capacitor (Cpre) 340 coupled between the input node 320 and the third node 333 for pre-emphasis, that is, capacitively coupling transitions in the input voltage to the third node 333, which may assist changing a voltage of the third node 333. In the embodiment, the third node 333 is commonly coupled to some of transistors across the first and the second amplifiers. Transition of the input signal at the input node 320 causes a one-shot pulse of pre-emphasis on the third node 333. For example, when the input signal becomes active and a signal level of the input node 320 becomes a logic high, the first transistor 301 and the fifth transistor 305 receive the active input signal which causes a signal level of the second node (PIN2B) 332 to become a logic low. At the same time, a high-pulse signal of the third node (PIN1T) 333 decreases capability of the seventh transistor 307 and the eight transistor 308 sharing the third node (PIN1T) 333 and increases capability of the third transistor 303 and the fourth transistor 304 where the third, fourth, seventh and eighth transistors, 303, 304, 307, and 308 share the third node (PIN1T) 333. The decrease of the capability of the seventh transistor 307 and the eighth transistor 308 and the increase of the capability of the third transistor 303 and the fourth transistor 304 may assist the signal level of the second node (PIN2B) 332 to transition to a logic low.

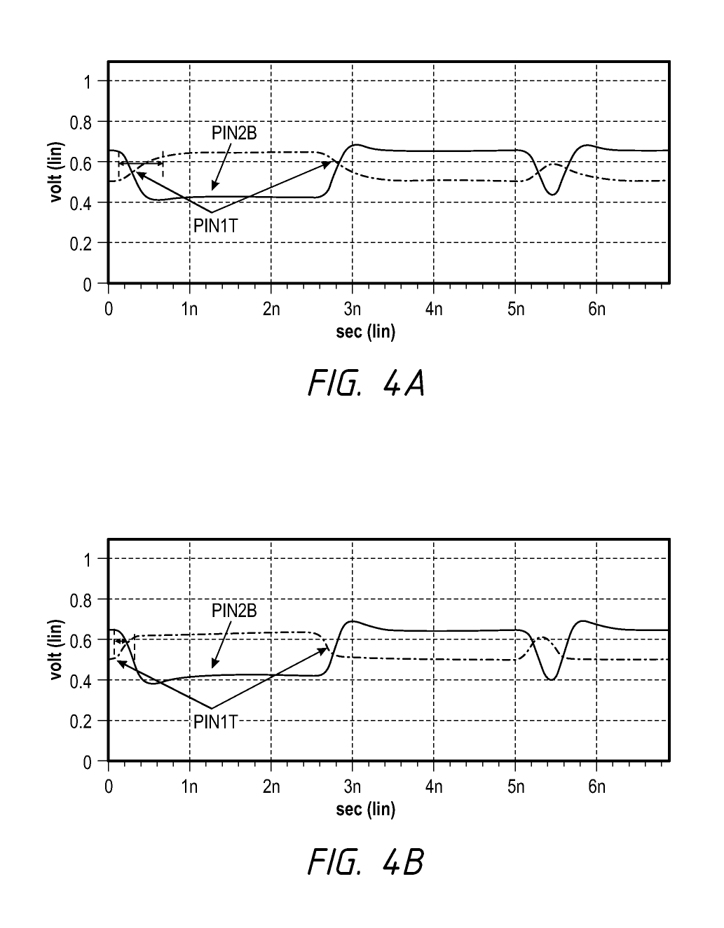

FIG. 4A is a timing diagram of internal signals of the input receiver circuit 100 of FIG. 1, without pre-emphasis by a capacitor Cpre, and FIG. 4B is a timing diagram of internal signals of the input receiver circuit according to an embodiment of the present disclosure, with pre-emphasis by a capacitor Cpre. An effect of the capacitor Cpre 340 can be observed by comparing FIGS. 4A and 4B showing behaviors of the signal level of the third node (PIN1T) and the signal level of the second node (PIN2B). When an active input signal causes a signal level of the input node higher, a signal level of the third node (PIN1T) increases and a signal level of the second node (PIN2B) decreases, as observed in FIGS. 4A and 4B. Due to a capacitive coupling through the capacitor Cpre, transistors 307 and 308 having their gates coupled to the third node (PIN1T) 333 become weaker and transistors 303 and 304 having their gates coupled to the third node (PIN1T) 333 become greater. Thus, the capacitor Cpre 340 accelerates a rise of the signal level of the third node (PIN1T) 333. For example, a rise time of the signal level of a node PIN1T of FIG. 1 shown in FIG. 4A is about twice as long as a rise time of the signal level of the third node (PIN1T) 333 shown in FIG. 4B. The pre-emphasis by the capacitor Cpre accelerates a discharge operation of the second node (PIN2B). Thus, signal propagation with pre-emphasis by the capacitive coupling of the capacitor Cpre may be faster than signal propagation of the input receiver circuit without the capacitor Cpre.

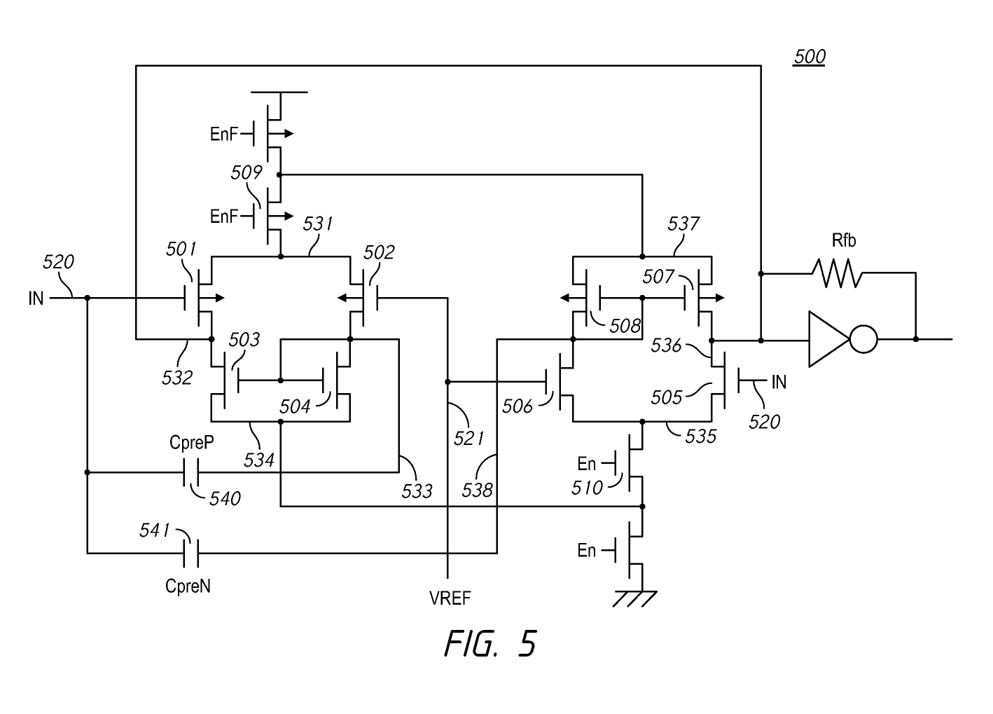

FIG. 5 is a circuit diagram of an example of an input receiver circuit 500 according to an embodiment of the present disclosure. For instance, an input buffer may include an input receiver circuit that does not share a node like the third node PIN1T in FIG. 3 among gates of the transistors while achieving a boost effect of the capacitive coupling. The input receiver circuit 500 of FIG. 5 may be used for any of the address input circuit 31, the command input circuit 33, or the clock input circuit 35 in FIG. 2. The input receiver circuit 500 includes an input node 520, a reference node 521, a first transistor 501 between a first node 531 and a second node 532, a second transistor 502, between the first node 531 and a third node 533, a third transistor 503 between the second node 532 and a fourth node 534, a fourth transistor 504 coupled between the third node 533 and the fourth node 534 in a similar configuration as the input receiver circuit 300 of FIG. 3. Furthermore, the input receiver circuit 500 may also include a fifth transistor 505 between a fifth node 535 and a sixth node 536, a sixth transistor 506 between the fifth node 535 and an eighth node 538, a seventh transistor 507 between the sixth node 536 and a seventh node 537, an eighth transistor 508 between the eighth node 538 and the seventh node 537. A ninth transistor 509 and a tenth transistor 510 may be included for receiving an activation signal and its complementary signal.

The input receiver circuit 500 of this embodiment in FIG. 5 differs from the QCR type input receiver circuit in FIG. 3 in that the input receiver circuit 500 includes a second capacitor (CpreN) 541 between the input node 520 and the eighth node 538 as an additional capacitor to a first capacitor (CpreP) 540 between the input node 520 and the third node 533 for pre-emphasis. In this embodiment of the input receiver circuit 500, the first capacitor 540 and the second capacitor 541 are coupled to the respective third and eighth nodes 533 and 538 which correspond to the third node (PIN1T) 333 in FIG. 3. Transition of the input signal at the input node 520 causes a one-shot pulse of pre-emphasis on the third node 533 and the eighth node 538. For example, when the input signal becomes active and a signal level of the input node 520 becomes a logic high, the first transistor 501 and the fifth transistor 505 receive the active input signal which causes a signal level of the second node 532 falls. At the same time, a high-pulse signal of the eighth node 538 decreases capability of the seventh transistor 507 and the eight transistor 508 sharing the eighth node 538 at their gates and the third node 533 increases capability of the third transistor 503 and the fourth transistor 504 sharing the third node 533 at their gates. The decrease of the capability of the seventh and eighth transistors 507 and 508 and the increase of the capability of the third and fourth transistors 503 and 504 assist the signal level of the second node 532 to fall faster.

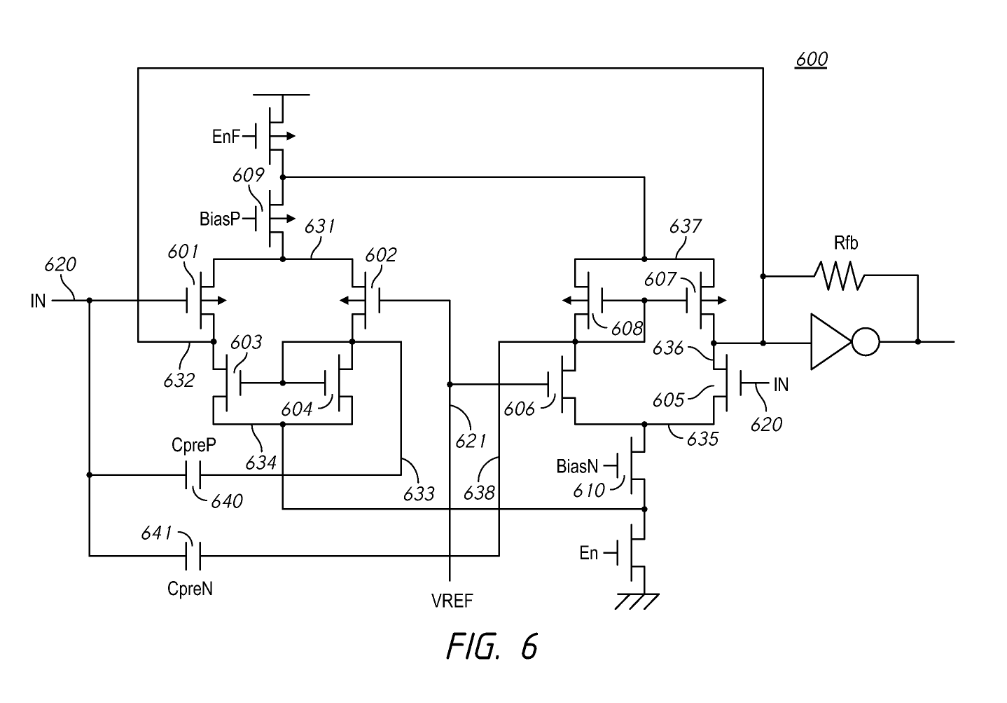

The structure of the input receiver circuit 500 in FIG. 5 may also be applied to an external-biasing type input receiver circuit. FIG. 6 is a circuit diagram of an example of an input receiver circuit according to an embodiment of the present disclosure. As for transistors 601 to 610 and nodes 620, 621, 631 to 638, the first capacitor 640 and the second capacitor 641 are in a similar configuration as the input receiver circuit 500 of FIG. 5. The input receiver circuit 600 of this embodiment in FIG. 6 differs from the input receiver circuit in FIG. 5 in that the input receiver circuit 600 has nodes for receiving bias signals. For example, a gate of the ninth transistor 609 is coupled to a first bias node that receives a first bias signal BiasP instead of the complementary activation signal, and a gate of the tenth transistor 610 is coupled to a second bias node that receives a second bias signal BiasN instead of the activation signal. The first bias signal BiasP and the second bias signal BiasN may be generated at a bias level generator (not shown). Thus, the bias signals received at the gate of the ninth transistor 609 and at the gate of the tenth transistor 610 may be provided to the input receiver circuit 600. Thus, the stability of the external-biasing type of input may be improved.

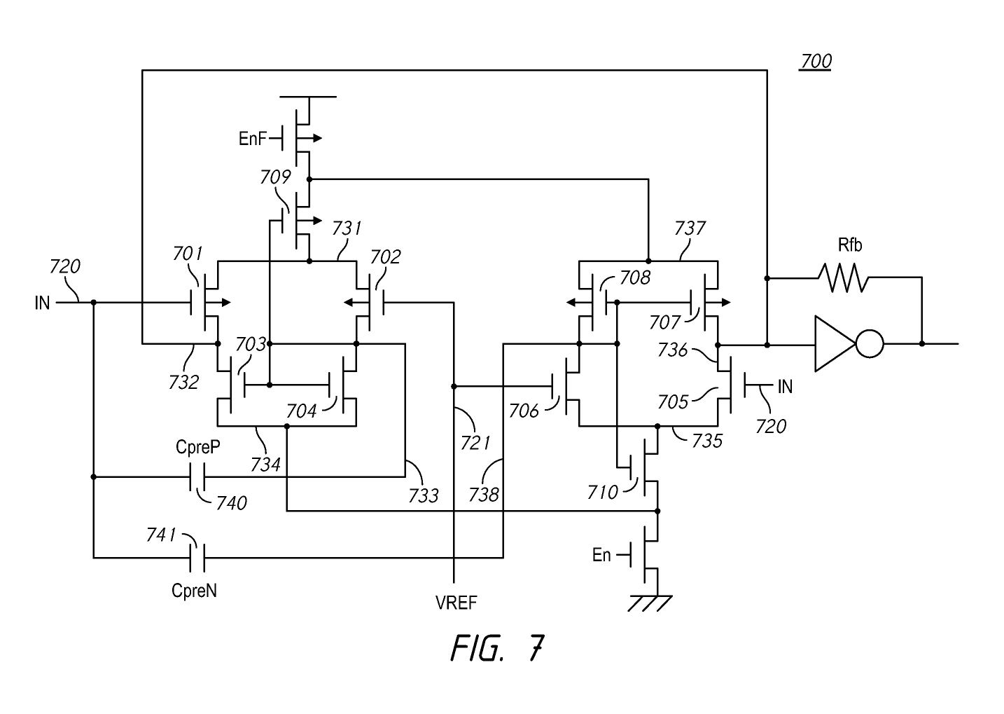

The structure of the input receiver circuit 500 in FIG. 5 may also be applied to an input buffer of self-biasing type. FIG. 7 is a circuit diagram of an example of an input receiver circuit 700 according to an embodiment of the present disclosure. As for transistors 701 to 710 and nodes 720, 721, 731 to 738, the first capacitor 740 and the second capacitor 741 are in a similar configuration as the input receiver circuit 500 of FIG. 5. However, a gate of the ninth transistor 709 is coupled to the third node 733 and a gate of the tenth transistor 710 is coupled to the eighth node 738, instead of an activation signal and its complementary signal. Thus, a signal on the third node 733 can be received as a bias signal at the gate of the ninth transistor 709 and a signal on the eighth node 738 can be received as a bias signal at the gate of the tenth transistor 710. Unlike the input receiver circuit 600 in FIG. 6, the bias signals do not need to be provided to the input receiver circuit 700, because the bias signals are provided from the third node 733 and the eighth node 738. Thus, the stability of the self-biasing type of input may be improved.

In one embodiment, it may be preferable to have two wirings on a same/different layer(s) with an insulator sandwiched between the two wirings, in order to have stable capacitance of the capacitor. The two wirings may be made of poly-silicon, metal, etc. In some embodiments, a MOS transistor may be used as the capacitor, for example, when the capacitance of the MOS transistor is stable. As known, however, the capacitance of a MOS transistor may fluctuate, thus may not be stable depending on a level of an input signal. For example, a range of the capacitance of the capacitor may be between 30 fF and 90 fF in case of double data rate fourth generation synchronous dynamic random-access memory (DDR4). The upper limit may be considered as around 100 fF because a maximum input terminal capacitance is specified as 1.3 pF in the specification of DDR4. Increasing the capacitance of the capacitor beyond the above value may not improve the performance of an input receiver circuit that includes the capacitor. Under this condition, a capacitor with the capacitance of about 90 fF is likely to provide smaller jitters than the capacitor with the capacitance of 30 fF or the 60 fF. The capacitor with smaller jitter enables the input receiver circuit to activate faster and accelerates a data rate of the input receiver circuit.

Although this invention has been disclosed in the context of certain preferred embodiments and examples, it will be understood by those skilled in the art that the inventions extend beyond the specifically disclosed embodiments to other alternative embodiments and/or uses of the inventions and obvious modifications and equivalents thereof. In addition, other modifications which are within the scope of this invention will be readily apparent to those of skill in the art based on this disclosure. It is also contemplated that various combination or sub-combination of the specific features and aspects of the embodiments may be made and still fall within the scope of the inventions. It should be understood that various features and aspects of the disclosed embodiments can be combined with or substituted for one another in order to form varying mode of the disclosed invention. Thus, it is intended that the scope of at least some of the present invention herein disclosed should not be limited by the particular disclosed embodiments described above.

What is claimed is:

1. An apparatus comprising:
an input node;
a reference node supplied with a reference voltage;
first, second, third and fourth nodes;
a first transistor coupled between the first node and the second node, the first transistor having a gate coupled to the input node;
a second transistor coupled between the first node and the third node, the second transistor having a gate coupled to the reference node;
a third transistor coupled between the second node and the fourth node, the third transistor having a gate coupled to the third node;
a fourth transistor coupled between the third node and the fourth node, the fourth transistor having a gate coupled to the third node; and
a capacitor coupled between the input node and the third node.

2. The apparatus of claim 1, further comprising:
fifth, sixth and seventh nodes;
a fifth transistor coupled between the fifth node and the sixth node, the fifth transistor having a gate coupled to the input node;
a sixth transistor coupled between the fifth node and the third node, the sixth transistor having a gate coupled to the reference node;
a seventh transistor coupled between the sixth node and the seventh node, the seventh transistor having a gate coupled to the third node; and
an eighth transistor coupled between the third node and the seventh node, the eighth transistor having a gate coupled to the third node.

3. The apparatus of claim 2, wherein each of the first transistor, the second transistor, the seventh transistor and the eighth transistor is of a first conductivity type and each of the third transistor, fourth transistor, fifth transistor and sixth transistor is of a second conductivity type.

4. The apparatus of claim 2, further comprising a ninth transistor coupled between the first node and the seventh node and a tenth transistor coupled between the fourth node and the fifth node.

5. The apparatus of claim 1, further comprising:
fifth, sixth, seventh and eighth nodes;
a fifth transistor coupled between the fifth node and the sixth node, the fifth transistor having a gate coupled to the input node;
a sixth transistor coupled between the fifth node and the eighth node, the sixth transistor having a gate coupled to the reference node;
a seventh transistor coupled between the sixth node and the seventh node, the seventh transistor having a gate coupled to the eighth node;
an eighth transistor coupled between the eighth node and the seventh node, the eighth transistor having a gate coupled to the eighth node; and
an additional capacitor coupled between the input node and the eighth node.

6. The apparatus of claim 5, wherein each of the first transistor, the second transistor, the seventh transistor and the eighth transistor is of a first conductivity type and each of the third transistor, fourth transistor, fifth transistor and sixth transistor is of a second conductivity type.

7. The apparatus of claim 5, further comprising a ninth transistor coupled between the first node and the seventh node and a tenth transistor coupled between the fourth node and the fifth node.

8. The apparatus of claim 7, wherein the ninth transistor has a gate coupled to the third node and the tenth transistor has a gate coupled to the eighth node.

9. The apparatus of claim 7, wherein the ninth transistor has a gate coupled to a first bias node and the tenth transistor has a gate coupled to a second bias node, and
wherein the first bias signal is supplied externally from the first bias node and the second bias signal is supplied externally from the second bias node.

10. The apparatus of claim 7, wherein the ninth transistor has a gate configured to receive a first activation signal and the tenth transistor has a gate configured to receive a second activation signal which is a complementary signal of the first activation signal.

11. An apparatus, comprising:
an input node supplied with an input signal;
a reference node supplied with a reference voltage;
a first amplifier that comprises:
first, second, third and fourth nodes;
a first transistor coupled between the first node and the second node, the first transistor having a gate coupled to the input node;
a second transistor coupled between the first node and the third node, the second transistor having a gate coupled to the reference node;
a third transistor coupled between the second node and the fourth node, the third transistor having a gate coupled to the third node; and
a fourth transistor coupled between the third node and the fourth node, the fourth transistor having a gate coupled to the third node,
a second amplifier that comprises:
fifth, sixth and seventh nodes;
a fifth transistor coupled between the fifth node and the sixth node, the fifth transistor having a gate coupled to the input node;
a sixth transistor coupled between the fifth node and the third node, the sixth transistor having a gate coupled to the reference node;
a seventh transistor coupled between the sixth node and the seventh node, the seventh transistor; and
an eighth transistor coupled between the third node and the seventh node,
an output node;
an inverter configured to receive a signal from the sixth node and further configured to provide an output signal to the output node;
a feedback resistor coupled between the sixth node and the output node; and
a first capacitor coupled between the input node and the third node.

12. The apparatus of claim 11, wherein the first transistor, the second transistor, the seventh transistor and the eighth transistor are P channel field effect transistors and the third transistor, the fourth transistor, the fifth transistor and the sixth transistor are N channel field effect transistors.

13. The apparatus of claim 11, wherein a gate of the seventh transistor and a gate of the eighth transistor are coupled to the third node.

14. The apparatus of claim 11, further comprising a second capacitor coupled between the input node and the eighth node,
wherein a gate of the seventh transistor and a gate of the eight transistor are coupled to the eighth node.

15. The apparatus of claim 11, further comprising a ninth transistor coupled between the first node and the seventh node and a tenth transistor coupled between the fourth node and the fifth node

16. The apparatus of claim 15, wherein the ninth transistor has a gate configured to receive a first activation signal and the tenth transistor has a gate configured to receive a second activation signal which is a complementary signal of the first activation signal.

17. The apparatus of claim 15, wherein the ninth transistor has a gate configured to receive a first bias signal and the tenth transistor has a gate configured to receive a second bias signal, and
wherein the first bias signal and the second bias signal are generated externally and supplied to the gate of ninth transistor and the gate of tenth transistor, respectively.

18. The apparatus of claim 15, wherein the ninth transistor has a gate coupled to the third node and the tenth transistor has a gate coupled to the eighth node.

19. The apparatus of claim 11, wherein the first capacitor comprises two wirings on a same layer and an insulator disposed between the two wirings.

20. The apparatus of claim 19, wherein the two wirings are made of poly-silicon or metal.
